(19) United States
(12) Patent Application Publication
(10) Pub. No.: US 2024/0158669 A1
(43) Pub. Date: May 16, 2024

(54) OPTICAL LAMINATE, OPTICAL MEMBER COMPRISING SAME, AND OPTICAL DISPLAY DEVICE INCLUDING SAME

(71) Applicant: SAMSUNG SDI CO., LTD., Yongin-si, Gyeonggi-do (KR)

(72) Inventors: Ji Ho KIM, Suwon-si (KR); Sung Hyun MUN, Suwon-si (KR); Kyoung Gon PARK, Suwon-si (KR); Jin Young LEE, Suwon-si (KR); Jae Hyun HAN, Suwon-si (KR); Il Jin KIM, Suwon-si (KR); Dong Myeong SHIN, Suwon-si (KR)

(21) Appl. No.: 18/547,954

(22) PCT Filed: Feb. 24, 2022
(86) PCT No.: PCT/KR2022/002704

§ 371 Date: Aug. 25, 2023

(30) Foreign Application Priority Data
Feb. 25, 2021 (KR) 10-2021-0026006

(51) Int. Cl. C09J 7/29; B32B 7/12; B32B 27/08; B32B 27/36; C09J 7/38

(52) U.S. Cl. CPC C09J 7/29; B32B 7/12; B32B 27/08; B32B 27/36; C09J 7/385; B32B 2255/10; B32B 2255/26; B32B 2255/28; B32B 2307/54; B32B 2307/748; B32B 2457/20; C09J 2203/326; C09J 2301/1242; C09J 2301/414; C09J 2433/006; C09J 2483/00

(57) ABSTRACT

Provided are: an optical laminate comprising a second adhesive layer, a second adhesive layer laminated on the second adhesive layer, and a light shield part laminated between the first adhesive layer and the second adhesive layer; an optical member comprising same; and an optical display device including same.

### TECHNICAL FIELD

The present invention relates to an optical laminate, an optical member including the same, and an optical display device including the same.

### BACKGROUND ART

Optical display devices generally include a display area in which an image is displayed and a non-display area surrounding the display area on a horizontal cross section. The non-display area includes a black matrix or a light blocking layer to prevent internal elements existing outside the display area from being visible from the outside.

In order to form a non-display area, a method of forming a light blocking layer on a lower surface of a window film, which has a hard coating layer formed on an upper surface thereof, is considered. The light blocking layer is formed by printing a composition for a light blocking layer on a lower surface of a base film constituting the window film in a roll-to-roll manner in units of cells, or by using a photoresist technique on the composition for a light blocking layer. The window film on which the light blocking layer is formed may be used by laminating an optical adhesive film, such as an optical clear adhesive (OCA) or an optical clear resin (OCR) on the side of the window film, on which the light blocking layer is formed, and then cutting the window film in a cell unit.

The method of simultaneously forming multiple cells in a roll-to-roll manner inevitably leads to defective phenomena including print flow patterns and print smearing, resulting in a substantial increase in discarded base film or window film, which has contributed to rising costs. In particular, in the case of small-sized displays such as mobile displays, a relatively large number of cells must be simultaneously formed as compared to large-sized displays, and thus a defect generation rate may be further increased. In addition, previously, one optical adhesive film is used, and thus, in order to increase the adhesion of both the base film and the optical element, a surface treatment process of the base film is necessarily required, which reduces the processability.

Meanwhile, recently, the development of foldable display devices has been continuously conducted. Folding inevitably causes stress between the window film, on which the light blocking layer is formed, and the optical adhesive film. The window film, which includes the light blocking layer, and the optical adhesive film have limitations in improving foldability.

The background art of the present invention is disclosed in Korean Patent Application Publication No. 2006-0027222.

### DISCLOSURE

### Technical Problem

The present invention is directed to providing an optical laminate having excellent processability and cost-reduction effects.

The present invention is also directed to providing an optical laminate capable of realizing excellent foldability.

The present invention is also directed to providing an optical laminate capable of realizing high adhesiveness and reworkability at the same time by allowing one surface and the other surface of the optical laminate to have different adhesiveness.

### Technical Solution

One aspect of the present invention relates to an optical laminate.

1. The optical laminate includes a second adhesive layer, a first adhesive layer laminated on the second adhesive layer, and a light blocking part laminated between the first adhesive layer and the second adhesive layer.

2. In 1, the light blocking layer may be formed at an edge of the first adhesive layer or the second adhesive layer.

3. In 1 and 2, a thickness of the light blocking layer may be about 0.01% to 50% of a thickness of the first adhesive layer or the second adhesive layer.

4. In 1 to 3, the first adhesive layer and the second adhesive layer may each have a storage modulus of about 400 kPa or less at −20° C.

5. In 1 to 4, the first adhesive layer and the second adhesive layer may each have a storage modulus of about 5 kPa to 50 kPa at 60° C.

6. In 1 to 5, each of the first adhesive layer and the second adhesive layer may be a (meth)acrylic adhesive layer.

7. In 1 to 6, the first adhesive layer may be formed of an adhesive layer composition including a monomer mixture for a hydroxyl group-containing(meth)acrylic based copolymer and an initiator.

8. In 7, the adhesive layer composition may further include one or more of organic particles and inorganic particles.

9. In 1 to 8, the second adhesive layer may be formed of an adhesive layer composition including a monomer mixture for a hydroxyl group-containing (meth)acrylic based copolymer, an initiator, and a silicone-containing. (meth)acrylic based compound.

10. In 9, the adhesive layer composition may further include one or more of organic particles and inorganic particles.

11. In 1 to 10, the optical laminate may further include one or more of a first protective layer and a second protective layer that are formed between the first adhesive layer and the second adhesive layer.

12. In 9, each of the first protective layer and the second protective layer may be in contact with at least one surface of the light blocking part.

13. In 11 and 12, the optical laminate may include the second adhesive layer, and the second protective layer, the first protective layer, and the first adhesive layer, which are sequentially laminated on an upper surface of the second adhesive layer, and the light blocking part may be formed between the second protective layer and the first protective layer.

14. In 11 to 13, the light blocking part may be formed at an edge of the second protective layer or the first protective layer.

15. In 11 to 14, each of the first protective layer and the second protective layer may include a (meth)acrylic based, epoxy based, or silicone based coating layer.

16. In 11 to 15, a lamination thickness of the second protective layer, the light blocking part, and the first protective layer may be about 50 μm or less.

17. In 1, the optical laminate may include the second adhesive layer, the first adhesive layer laminated on an upper surface of the second adhesive layer, and the light blocking part laminated between the second adhesive layer and the first adhesive layer, and further include a second adherend laminated on a lower surface of the second adhesive layer and a first adherend laminated on an upper surface of the first adhesive layer.

18. In 1 and 17, the light blocking part may be formed at an edge of the first adhesive layer or the second adhesive layer.

An optical member of the present invention includes the optical laminate of the present invention.

An optical display device of the present invention includes the optical laminate of the present invention.

### Advantageous Effects

The present invention can provide an optical laminate having excellent processability and cost-reduction effects.

The present invention can provide an optical laminate capable of realizing excellent foldability.

The present invention can provide an optical laminate capable of realizing high adhesiveness and reworkability at the same time by allowing one surface and the other surface of the optical laminate to have different adhesiveness.

### DESCRIPTION OF DRAWINGS

FIG. 1 is a cross-sectional view of an optical laminate according to one embodiment of the present invention.

FIG. 2. is an exploded perspective view of the optical laminate of FIG. 1.

FIG. 3 is a cross-sectional view of an optical laminate according to another embodiment of the present invention.

FIG. 4 is a cross-sectional view of an optical laminate according to still another embodiment of the present invention.

FIG. 5 is a schematic diagram of a process of manufacturing an optical laminate according to one embodiment of the present invention.

FIG. 6 is a schematic diagram of a process of manufacturing an optical laminate according to another embodiment of the present invention.

FIGS. 7A and 7B are a top plan view and a cross-sectional view, respectively, of a specimen for measurement of peel strength.

FIG. 8 is a cross-sectional view illustrating the specimen being driven during peel strength measurement.

### MODES OF THE INVENTION

Hereinafter, embodiments of the present application will be described in more detail with reference to the accompanying drawings. However, the technology disclosed in the present application is not limited to the embodiments described herein and may be embodied in other forms, However, the embodiments introduced herein are provided so that the disclosed content may be thorough and complete, and the spirit of the present application may be sufficiently conveyed to those skilled in the art.

In order to clearly express components of each device in the drawing, the size of the component, such as width or thickness, is slightly enlarged, and the width or thickness of the components is not intended to limit the scope of the present invention. In a plurality of drawings, like reference numerals refer to substantially the same components.

In the present specification, the terms “upper portion” and “lower portion” are defined based on the drawings, and depending on the point of view, “upper portion” may be changed to “lower portion” and “lower portion” may be changed to “upper portion”. In addition, when one element is referred to as being “on” another element, it refers to not only a case in which the element is formed directly located “on” the other element but also a case in which another structure is interposed therebetween. On the other hand, when one element is referred to as being “directly on” or “directly above”, or being “directly formed on” another element, it indicates that another structure, such as an intermediate body, is not interposed therebetween.

As used herein, the term “(meth)acrylic” may refer to acrylic and/or methacrylic.

As used herein, the term “copolymer” may include a polymer or a resin.

As used herein, the term “glass transition temperature of a homopolymer” may refer to a glass transition temperature measured on a homopolymer of a measurement target monomer using DSC Discovery (TA Instrument Inc.) Specifically, a homopolymer of a measurement target monomer may be heated to about 180° C. at a heating rate of about 20° C./min, followed by slowly cooling the homopolymer to about −100° C., and then heating to about 100° C. at a heating rate of about 10° C./min to obtain data of an endothermic transition curve, and then an inflection point of the endothermic transition curve may be determined as the glass transition temperature.

As used herein, “storage modulus” is a value measured using an ARES G2 rheometer (TA Instruments), which is a dynamic viscoelasticity measurement device, at a shear rate of 1 rad/sec and a strain of 1% under auto strain conditions. Specifically, the storage modulus is a value measured on a specimen while heating the specimen from −60° C. to 100° C. at a heating rate of 5° C./min in a state in which a normal force of 1.0 N is applied to the specimen using 8 mm jigs, wherein the specimen is prepared by laminating a plurality of adhesive layers to prepare a sample having a thickness of 800 μm, and perforating the laminate using an 8 mm-diameter punching machine.

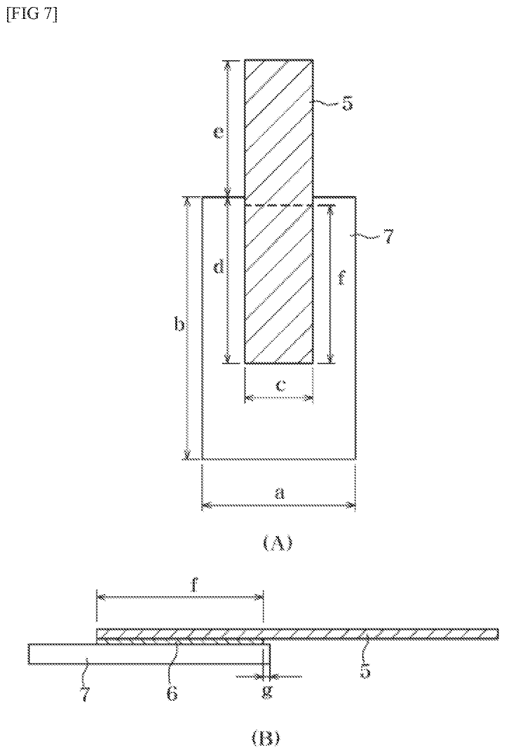

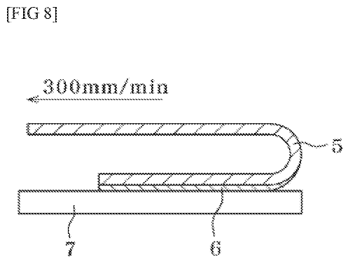

For measuring “peel strength” in the present specification, referring to FIG. 7, an adhesive layer 6 and a PET film 5 subjected to treatment twice (total dose: 156 doses) while plasma discharging at 78 doses using a corona treatment device were sequentially laminated on a high-strength glass plate 7, and in FIG. 7, “a” is 50 mm, “b” is 100 mm, “c” is 25 mm, “d” is 70 mm, “e” is 50 mm, “f” is 60 mm, and “g” is 10 mm. The adhesive layer 6 had a thickness of 25 μm and the PET film 5 had a thickness of 75 μm. A specimen of FIG. 7 was prepared and the prepared specimen left at 25° C. for 30 minutes. The specimen was fixed to TA.XT_Plus Texture Analyzer (Stable Micro Systems), and peel strength of the specimen was measured at 25° C. by a method shown in FIG. 8, Referring to FIG, 8, one end of the PET film 5, which is not laminated with the adhesive layer 6, was bent at a peeling angle of 180° and one end of the PET film was pulled at a speed of 300 mm/min using the TA.XT_Plus Texture Analyzer to measure peel strength at which the adhesive layer 6 was peeled off from the high-strength glass plate 7.

In the present specification, when referring to numerical ranges “X to Y” refers to “greater than or equal to X and less than or equal to V (X≤and≤V).”

An optical laminate of the present invention includes a second adhesive layer, a first adhesive layer laminated on the second adhesive layer, and a light blocking part laminated between the second adhesive layer and the first adhesive layer. The first adhesive layer and the second adhesive layer are formed to face each other.

The optical laminate of the present invention may simultaneously perform a function of adhering a first adherend and a second adherend, which are different from each other, to each other and a function of realizing a non-display area and a display area when applied to an optical display device. Although not particularly limited, in the present specification, it is defined that the first adherend is laminated to the first adhesive layer, and the second adherend is laminated to the second adhesive layer.

In addition, the optical laminate of the present invention can simultaneously achieve high adhesiveness and reworkability, which are difficult to be compatible with each other, and can also realize excellent foldability, by easily controlling both the first adhesive layer and the second adhesive layer.

An optical laminate cut to a size of 100 mm×100 mm (length×width) was laminated to a high-strength glass plate such that a second adhesive layer is laminated to the high-strength glass plate to prepare a specimen. The specimen was placed on a hot plate and left at 80° C. for 10 minutes, followed by peeling the optical laminate from the high-strength glass plate at a speed of 2400 mm/min, and the “reworkability” was determined by determining whether the second adhesive layer of the optical laminate residue on the high-strength glass plate was present and whether the optical laminate was destroyed. The optical laminate of the present invention had excellent reworkability, especially high-temperature reworkability, since there is no residue of the second adhesive layer in the high-strength glass plate and the optical laminate is not destroyed during the above determination process.

The “foldability” may be evaluated by the following method.

### Method of Evaluating Foldability

A module specimen was fabricated by sequentially stacking a window film, an optical laminate, and an organic light-emitting diode (OLED) display panel. The window film, the optical laminate, and the OLED panel used in fabrication of the module were as follows.
Window film: a PET film (thickness: 100 μm, Cosmoshine TA015, Toyobo Co., Ltd.) was used.
Optical laminate: the optical laminate of the present invention.
OLED panel: a PET film (thickness: 100 μm, Cosmoshine TA015, Toyobo Co., Ltd.) was used.

The fabricated module specimen was cut to a size of 170 mm×110 mm (length×width), and subjected to 100,000 cycles of folding at −20° C. to evaluate the generation of bubbles, cracks, and delamination in the module specimen. When folding, the module specimen was folded in a longitudinal direction thereof and a direction of the OLED panel such that a bent portion of the specimen had a radius of curvature of 1.5 mm at a folding rate of 30 cycles per minute, and at this point, 1 cycle refers to an operation of folding the specimen to have the radius of curvature, followed by unfolding the specimen back to an original state thereof. The foldability may be evaluated at 25° C. The optical laminate of the present invention can realize excellent foldability since bubbles, cracks, and delamination do not occur during the above evaluation.

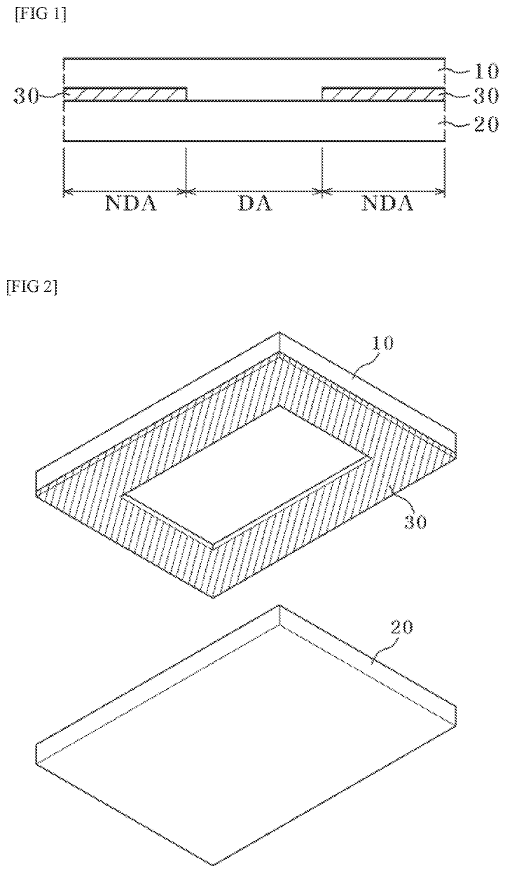

In addition, the optical laminate of the present invention has an excellent effect of reducing processability and costs by being manufactured by the method described above. That is, the conventional method of simultaneously forming a plurality of cells including a light blocking part (e.g., a light blocking part (30) in FIG. 1) on a base film or window film in a roll-to-roll manner inevitably leads to defective phenomena, such as print flow patterns and print smearing, resulting in a substantial increase in discarded base film or window film, which has contributed to rising costs, but the optical laminate of the present invention does not have the above-described problems and thus is excellent in processability and cost reduction.

Hereinafter, an optical laminate according to one embodiment of the present invention will be described with reference to FIGS. 1 and 2.

Referring to FIG. 1, the optical laminate includes a first adhesive layer (10), a light blocking part (30), and a second adhesive layer (20).

### Light Blocking Part (30)

The light blocking part (30) is formed on at least a portion of an interface between the first adhesive layer (10) and the second adhesive layer (20). Specifically, the light blocking part (30) is impregnated into the interface between the first adhesive layer (10) and the second adhesive layer (20). As shown in FIG. 1, the term “impregnation” is a concept including a case in which the light blocking part (30) penetrates a portion of the first adhesive layer (10) and is present inside the first adhesive layer (10) by being in contact with one surface of the second adhesive layer (20) (an upper surface of the second adhesive layer) or a case in which the light blocking part (30) penetrates a portion of each of the first adhesive layer (10) and the second adhesive layer (20) and is present inside in the first adhesive layer (10) and the second adhesive layer (20). The light blocking part (30) is not formed as a separate layer with respect to the first adhesive layer (10) and/or the second adhesive layer (20), and thus the optical display device can be reduced in thickness.

The light blocking part (30) is formed at an edge of the first adhesive layer (10) and/or the second adhesive layer (20). Specifically, as shown in FIG. 2, the light blocking part (30) may be formed with a portion of an inside of the first adhesive layer (10) open. That is, the light blocking part (30) may be formed in the shape of a closed curve or a closed polygon, including an inner side and an outer side, and may include a partially empty area therein. The inner side of the light blocking part (30) refers to an empty space of the light blocking part forming a closed curve or a closed polygon. The outer side of the light blocking part (30) refers to a surface opposite to the inner side of the light blocking part (30).

The light blocking part (30) may correspond to a non-display area (NDA) when the optical laminate is applied to an optical display device. The optical laminate includes a display area (DA) and the non-display area (NDA). The display area (DA) is a part that performs a display function of the optical display device and allows an image to be visible through a screen. On the other hand, the non-display area (NDA) is not directly involved in the display function. The non-display area (NDA.) is located at an edge of the display area (NDA) and surrounds and protects the display area (DA), and covers a printed circuit board, driving chips, and the like for driving an image so as not to be visible to a user.

A thickness of the light blocking part (30) may be less than a thickness of the first adhesive layer (10) or the second adhesive layer (20). This allows the light blocking part (30) to be included in the interface between the first adhesive layer (10) and the second adhesive layer (20), and also ensures flexural reliability of the optical laminate.

In one embodiment, the thickness of the light blocking part (30) may be about 0.01% to 50%, for example, 0.01%, 0.1%, 1%, 5%, 10%, 15%, 20%, 25%, 30%, 35%, 40%, 45%, and 50%, and preferably about 1% to 30% of the thickness of the first adhesive layer (10) or the second adhesive layer (20). Within the above range, the light blocking part (30) can be included in the interface between the first adhesive layer and the second adhesive layer, and may not affect the flexural reliability of the optical laminate.

The thickness of the light blocking part (30) may range from about 1.0 μm to 25 μm, for example, 1 μm, 5 μm, 10 μm, 15 μm, 20 μm, and 25 μm, and preferably from about 1.0 μm to 10 μm. Within the above range, the light blocking part (30) n ay be included in the interface between the first adhesive layer and the second adhesive layer, light blocking properties can be secured, and the optical laminate can be reduced in thickness.

The light blocking part (30) may be formed of a thermocurable or photocurable composition, or a composition for the light blocking part, which includes at least one of a dye and a pigment providing a light blocking effect.

In one embodiment, the composition for the light blocking part may include a pigment, an organic resin binder, and an initiator. By including the above components, it is possible to form the light blocking part (30) that has a smaller thickness and is easier to implement all of the effects of the present invention. The composition for the light blocking part may further include one or more of a reactive unsaturated compound, a solvent, and an additive.

The pigment may include carbon black, a mixed pigment of silver-tin alloys, or a combination thereof. Examples of the carbon black include graphitized carbon, furnace black, acetylene black, ketjen black, and the like, but the present invention is not limited thereto. The pigment may be included as a pigment dispersion, but the present invention is not limited thereto.

The organic resin binder may include an acrylic based resin, a polyimide based resin, a polyurethane based resin, or a combination thereof. The acrylic based resin may include methacrylic acid/benzyl methacrylate copolymer, methacrylic acid/benzyl methacrylate/styrene copolymer, methacrylic acid/benzyl methacrylate/2-hydroxyethylmethacrylate copolymer, methacrylic acid/benzyl methacrylate/styrene/2-hydroxyethylmethacrylate copolymer, and the like, and the polyurethane based resin may be an aliphatic polyurethane resin. However, the present invention is not limited thereto.

The initiator may include one or more of a photopolymerization initiator and a heat polymerization initiator.

The photopolymerization initiator may include acetophenone based compounds, benzophenone based compounds, thioxanthone based compounds, benzoin based compounds, triazine based compounds, and morpholine based compounds, but the present invention is not limited thereto. The heat polymerization initiator may include peroxide, azo-based compounds, and the like, but the present invention is not limited thereto.

The reactive unsaturated compound is a compound having at least two reactive unsaturated groups, for example, a (meth)acrylate group, and examples of the reactive unsaturated compound may include ethylene glycol di(meth)acrylate, ethylene glycol di(meth)acrylate, diethylene glycol di(meth)acrylate, triethylene glycol di(meth)acrylate, triethylene glycol di(meth)acrylate, 1,6-hexanediol di(meth)acrylate, 1,6-hexanediol di(meth)acrylate, pentaerythritol tri(meth)acrylate, pentaerythritol tetra(meth)acrylate, dipentaeythritol penta(meth)acylate dipentaeythritol hexa(meth)acrylate, bisphenol A epoxy (meth)acrylate, ethylene glycol monomethylether (meth)acrylate, trimethylolpropane tri(meth)acrylate, and tris(meth)acryloyloxyethyl phosphate, but the present invention is not necessarily limited thereto.

The solvent may include glycol ethers, such as ethylene glycol methylether, ethylene glycol ethylether, propylene glycol methylether, and the like; cellosolve acetates, such as methyl cellosolve acetate, ethyl cellosolve acetate, diethyl cellosolve acetate, and the like; carbitols, such as methylethyl carbitol, diethyl carbitol, diethylene glycol monomethylether, diethylene glycol monoethylether, diethylene glycol dimethylether, diethylene glycol methylethylether, diethylene glycol diethylether, and the like; and propylene glycol alkylether acetates, such as propylene glycol methylether acetate, propylene glycol propylether acetate, and the like, but the present invention is not limited thereto.

The additive may include one or more additives well-known in the art, such as ultraviolet (UV) absorbents, silane coupling agents, and the like.

The composition for the light blocking part may include about 1 to 50 wt % of the pigment, about 0.5 to 20 wt % of the organic resin binder, about 0.1 to 10 wt % of the initiator, and the balance of a solvent, Within the above range, the light blocking part having a thin thickness can be formed and an excellent light blocking effect can be exhibited. The composition for the light blocking part may further include 1 to 20 wt % of the reactive unsaturated compound.

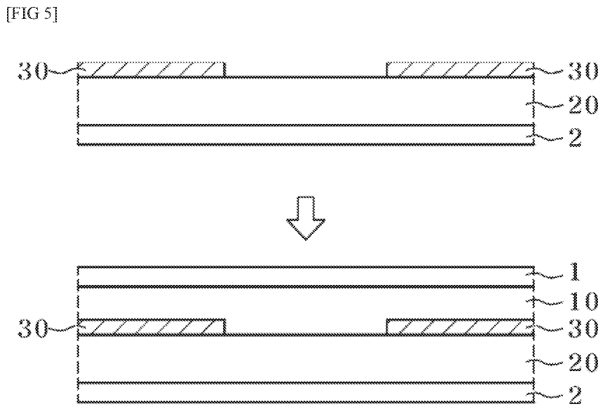

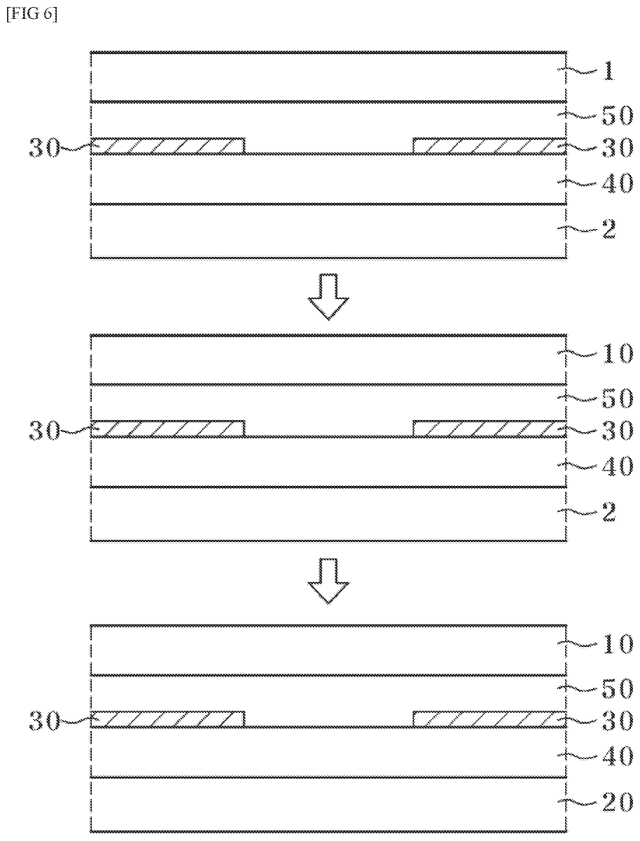

A method of forming the light blocking part (30) on the first adhesive layer (10) or the second adhesive layer (20) will be described in more detail with reference to FIGS. 5 and 6.

### First Adhesive Layer (10) and Second Adhesive Layer (20)

The first adhesive layer (10) and the second adhesive layer (20) may fix the light blocking part (30) formed in the interface therebetween, thereby enabling the optical laminate to provide stable light blocking properties. Since the first adhesive layer (10) and the second adhesive layer (20) are controlled in properties and/or compositions as described above, the entire optical laminate including the light blocking part (30) may have excellent foldability.

Since the first adhesive layer (10) and the second adhesive layer (20) are formed to face each other, the first adherend and the second adherend having different surface characteristics can be adhered to each other. The optical laminate of the present invention can simultaneously achieve high adhesiveness and reworkability, which are difficult to be compatible with each other, by easily controlling both the first adhesive layer (10) and the second adhesive layer (20).

The first adhesive layer (10) may have a storage modulus equal to or different from that of the second adhesive layer (20) at −20° C. to 60° C.

The first adhesive layer (10) and the second adhesive layer (20) may each have a storage modulus at 25° C. of about 10 kPa to 100 kPa, for example, 10 kPa, 20 kPa, 30 kPa, 40 kPa, 50 kPa, 60 kPa, 70 kPa, 80 kPa, 90 kPa, or 100 kPa, and preferably 20 kPa to 70 kPa. Within the above range, the optical laminate may have excellent handling/processability and room-temperature flexural reliability, and may facilitate the formation and impregnation of the light blocking part between the first adhesive layer and the second adhesive layer.

The first adhesive layer (10) and the second adhesive layer (20) each have a storage modulus at −20° C. of about 400 kPa or less, for example, 40 kPa, 50 kPa, 60 kPa, 70 kPa, 80 kPa, 90 kPa, 100 kPa, 110 kPa, 120 kPa, 130 kPa, 140 kPa, 150 kPa, 160 kPa, 170 kPa, 180 kPa, 190 kPa, 200 kPa, 210 kPa, 220 kPa, 230 kPa, 240 kPa, 250 kPa, 260 kPa, 270 kPa, 280 kPa, 290 kPa, 300 kPa, 310 kPa, 320 kPa, 330 kPa, 340 kPa, 350 kPa, 360 kPa, 370 kPa, 380 kPa, 390 kPa, or 400 kPa, preferably 40 kPa to 300 kPa, and more preferably more than 50 kPa and less than or equal to 200 kPa, Within the above range, the adhesive layer may exhibit excellent flexibility at low temperature so that flexural reliability of the optical laminate at low temperature s excellent, and it is helpful for implementing the function of the light blocking part.

The first adhesive layer (10) and the second adhesive layer (20) may each have a storage modulus at 60 of about 5 kPa to 50 kPa, for example, 5 kPa, 10 kPa, 15 kPa, 20 kPa, 25 kPa, 30 kPa, 35 kPa, 40 kPa, 45 kPa, or 50 kPa, and preferably 10 kPa to 45 kPa. Within the above range, the optical laminate has excellent flexural reliability under thermal shock between low and high temperatures conditions and under high temperature and/or high humidity conditions, and it is helpful for implementing the function of the light blocking part.

The first adhesive layer (10) and the second adhesive layer (20) may each have a. peel strength at 25° C. of about 700 gf/in. (=gf/inch) or more, for example, 700 gf/in., 750 gf/in., 800 gf/in., 850 gf/in., 900 gf/in., 950 gf/in., 1000 gf/in., 1050 gf/in., 1100 gf/in., 1150 gf/in., or 1250 gf/in., and specifically, 700 gf/in. to 1200 gf/in. Within the above range, when the adhesive layer is adhered to the adhered, the adhesive layer may be stably fixed to the adherend at room temperature to protect the adherend, and delamination between the first adhesive layer or the second adhesive layer and the light blocking part may be prevented.

The first adhesive layer (10) and the second adhesive layer (20) may be formed of the same or different adhesive layer compositions. Preferably, the first adhesive layer (10) is formed of an adhesive layer composition different from that of the second adhesive layer (20), so that the optical laminate can perform two or more functions by having different physical properties on one surface and the other surface. For example, the optical laminate may simultaneously realize high adhesiveness and reworkability.

Here, the term “different adhesive layer composition” may include not only a case in which the components of the adhesive layer composition are different, but also a case in which physical properties, chemical properties, mechanical properties, and the like are different even the components are of the same type.

The first adhesive layer (10) or the second adhesive layer (20) may be formed of a (meth)acrylic based, silicone based, epoxy based, or urethane based adhesive layer composition, but the present invention is not limited thereto. Preferably, the first adhesive layer (10) or the second adhesive layer (20) may be formed of a (meth)acrylic based adhesive layer composition in consideration of ease of obtaining the material, ease of handling, ease of realizing the properties, and the like,

In one embodiment, the adhesive layer composition may include a monomer mixture of a (meth)acrylic based monomer and an initiator, and the monomer mixture may form a hydroxyl group-containing (meth)acrylic based copolymer. The monomer mixture may include a hydroxyl group-containing (meth)acrylic acid ester and a comonomer, a homopolymer of which has a glass transition temperature of 0° C. or less, and specifically, −100° C. to 0° C.

The hydroxyl group-containing (meth)acrylic acid ester can reduce storage modulus of the first adhesive layer or the second adhesive layer at low temperature and at room temperature and can increase adhesive strength of the adhesive layer. The hydroxyl group-containing (meth)acrylic acid ester may include a (meth)acrylic acid ester containing a C4 to C20 alkyl group having at least one hydroxyl group. Specifically, the hydroxyl group-containing (meth)acrylic acid ester may include one or more of 4-hydroxybutyl (meth)acrylate, 2-hydroxybutyl (meth)acrylate, and 6-hydroxyhexyl (meth)acrylate. In the monomer mixture, the hydroxyl group-containing (meth)acrylic acid ester may be included in an amount of about 0.5 wt % to 30 wt %, for example, about 0.5 wt %, about 1 wt %, about 5 wt %, about 10 wt %, about 15 wt %, about 20 wt %, about 25 wt %, or about 30 wt %, and specifically, about 1 wt % to 25 wt %. Within the above range, the adhesive layer can have excellent foldability at room temperature and low temperature and exhibit excellent adhesive strength.

The comonomer may include one or more of an alkyl group-containing (meth)acrylic acid ester, an ethylene oxide group-containing monomer, a propylene oxide group-containing monomer, an amine group-containing monomer, an amide group-containing monomer, an alkoxy group-containing monomer, a phosphate group-containing monomer, a sulfonic acid group-containing monomer, a phenyl group-containing monomer, and a silane group-containing monomer. In the monomer mixture, the comonomer may be included in an amount of about 70 wt % to 99.5 wt %, for example, 70 wt %, 75 wt %, 80 wt %, 85 wt %, 90 wt %, 95 wt %, 99 wt %, or 99.5 wt %, and specifically 75 wt % to 99 wt %, Within the above range, the adhesive layer can have excellent foldability at room temperature and low temperature and exhibit excellent adhesive strength.

The alkyl group-containing (meth)acrylic acid ester may form a matrix of the adhesive layer and improve mechanical properties of the adhesive layer. The alkyl group-containing (meth)acrylic acid ester may include an unsubstituted C1 to C20 linear or branched alkyl group-containing (meth)acrylic acid ester. For example, the alkyl group-containing (meth)acrylic acid ester may include one or more of methyl (meth)acrylate, ethyl (meth)acrylate, propyl (meth)acrylate, n-butyl (meth)acrylate, t-butyl (meth)acrylate, iso-butyl (meth)acrylate, pentyl (meth)acrylate, hexyl (meth)acrylate, heptyl (meth)acrylate, ethylhexyl (meth)acrylate, octyl (meth)acrylate, isooctyl (meth)acrylate, nonyl (meth)acrylate, decyl (meth)acrylate, and lauryl (meth)acrylate.

The ethylene oxide group-containing monomer may include at least one (meth)acrylate monomer containing one or more ethylene oxide groups (—CH₂CH₂O—). For example, the ethylene oxide group-containing monomer may include any of polyethylene oxide alkyl ether (meth)acrylates, such as polyethylene oxide monomethyl ether (meth)acrylate, polyethylene oxide monoethyl ether (meth)acrylate, polyethylene oxide monopropyl ether (meth)acrylate, polyethylene oxide monobutyl ether (meth)acrylate, polyethylene oxide monopentyl ether (meth)acrylate, polyethylene oxide dimethyl ether (meth)acrylate, polyethylene oxide diethyl ether (meth)acrylate, polyethylene oxide monoisopropyl ether (meth)acrylate, polyethylene oxide monoisobutyl ether (meth)acrylate, and polyethylene oxide mono-tea-butyl ether (meth)acrylate, but the present invention is not necessarily limited thereto.

The propylene oxide group-containing monomer may include any of polypropylene oxide alkyl ether (meth)acrylates, such as polypropylene oxide monomethyl ether (meth)acrylate, polypropylene oxide monoethyl ether (meth)acrylate, polypropylene oxide monopropyl ether (meth)acrylate, polypropylene oxide monobutyl ether (meth)acrylate, polypropylene oxide monopentyl ether (meth)acrylate, polypropylene oxide dimethyl ether (meth)acrylate, polypropylene oxide diethyl ether (meth)acrylate, polypropylene oxide monoisopropyl ether (meth)acrylate, polypropylene oxide monoisobutyl ether (meth)acrylate, polypropylene oxide mono-tert-butyl ether (meth)acrylate, but the present invention is not necessarily limited thereto.

The amine group-containing monomer may include any of amine group-containing (meth)acrylic monomers, such as monomethylaminoethyl (meth)acrylate, monoethylaminoethyl (meth)acrylate, monomethylaminopropyl (meth)acrylate, monoethylaminopropyl (meth)acrylate, dimethylaminoethyl (meth)acrylate, diethylaminoethyl (meth)acrylate, N-tert-butylaminoethyl (meth)acrylate, and methacryloxyethyltrimethyl ammonium chloride (meth)acrylate, but the present invention is not necessarily limited thereto,

The amide group-containing monomer may include any of amide group-containing (meth)acrylic monomers, such as (meth)acrylamide, N-methyl acrylamide, N-methyl methacrylamide, N-methylol (meth)acrylamide, N-methoxymethyl (meth)acrylamide, N,N-methylene bis(meth)acrylamide, and 2-hydroxylethyl acrylamide, but the present invention is not necessarily limited thereto.

The alkoxy group-containing monomer may include any of 2-methoxyethyl (meth)acrylate, 2-methoxypropyl (meth)acrylate, 2-ethoxypropyl (meth)acrylate, 2-butoxypropyl (meth)acrylate, 2-methoxypentyl (meth)acrylate, 2-ethoxypentyl (meth)acrylate, 2-butoxyhexyl (meth)acrylate, 3-methoxypentyl (meth)acrylate, 3-ethoxypentyl (meth)acrylate, and 3-butoxyhexyl (meth)acrylate, but the present invention is not necessarily limited thereto.

The phosphate group-containing monomer may include any of phosphate group-containing acrylic monomers, such as 2-methacryloyloxyethyldiphenylphosphate (meth)acrylate, trimethacryloyloxyethylphosphate (meth)acrylate, and triacryloyloxyethylphosphate (meth)acrylate, but the present invention is not necessarily limited thereto.

The sulfonic acid group-containing monomer may include any of sulfonic acid group-containing acrylic monomers, such as sodium sulfopropyl (meth)acrylate, sodium 2-sulfoethyl (meth)acrylate, and sodium 2-acrylamido-2-methylpropane sulfonate, but the present invention is not necessarily limited thereto.

The phenyl group-containing monomer may include any of phenyl group-containing acrylic vinyl monomers such as p-tert-butylphenyl (meth)acrylate, o-biphenyl (meth)acrylate, and phenoxyethyl (meth)acrylate, but the present invention is not necessarily limited thereto.

The silane group-containing monomer may include any of silane group-containing vinyl monomers such as 2-acetoacetoxyethyl (meth)acrylate, vinyltrimethoxysilane, vinyltriethoxysilane, vinyl tris(2-methoxyethyl)silane, vinyltriacetoxysilane, and (meth)acryloyloxypropyltrimethoxysilane, but the present invention is not necessarily limited thereto.

The monomer mixture may further include a heteroalicyclic group-containing monomer.

The heteroalicyclic group-containing monomer can help to achieve a reversible peel strength change even at repeated temperature changes between room temperature and high temperature. The heteroalicyclic group-containing monomer may have a glass transition temperature of the homopolymer of about 10° C. to 200° C., and preferably 30° C. to 180° C. Within the above range, the peel strength of the adhesive layer can be increased.

The heteroalicyclic group-containing monomer may include one or more of N-(meth)acryloylmorpholine and N-(meth)acryloylpyrrolidone. Preferably, the heteroalicyclic group-containing monomer includes N-(meth)acryloylmorpholine, thereby increasing the peel strength at room temperature of the present invention.

The heteroalicyclic group-containing monomer may be included in an amount of about 0.1 wt % to 20 wt %, for example, about 0.1 wt %, about 0.5 wt %, about 1 wt %, about 5 wt %, about 10 wt %, about 15 wt %, or about 20 wt %, and preferably about 0.5 wt % to about 15 wt % or about 1 wt % to about 10 wt %, in the monomer mixture. Within the above range, the optical laminate may have excellent flexural reliability at low temperature and high temperature and/or high humidity.

The initiator can form a (meth)acrylic based copolymer from the monomer mixture or can cure the (meth)acrylic based copolymer. The initiator may include one or more of a photopolymerization initiator and a heat polymerization initiator. The photopolymerization initiator induces any initiator as long as the initiator can realize a crosslinking structure by deriving polymerization of the radical polymerizable compound during curing through light irradiation or the like. For example, benzoin based, acetophenone based, hydroxy ketone based, amino ketone based, phosphine oxide based photoinitiators, and the like may be used. The heat polymerization initiator is not particularly limited as long as it can realize the crosslinking structure by inducing polymerization of a polymerizable compound, and may use, for example, any typical initiator such as azo based, peroxide based, and redox compounds.

The initiator may be included in an amount of about 0.01 parts by weight to 5 parts by weight, specifically 0.05 parts by weight to 3 parts by weight, and more specifically 0.1 parts by weight to 1 parts by weight, based on 100 parts by weight of the monomer mixture. Within the above range, the initiator allows complete curing of the adhesive layer, can prevent deterioration in transmittance of the adhesive layer due to residual initiator, can reduce bubble generation in the adhesive layer, and can exhibit excellent reactivity.

The adhesive layer composition may further include one or more of organic particles and inorganic particles.

The organic particles allow the adhesive layer to exhibit excellent foldability at room temperature and high temperature, excellent low temperature and/or room temperature viscoelasticity, and exhibit stable high temperature viscoelasticity due to a crosslinked structure thereof. In addition, the organic particles can increase a storage modulus at high temperature, thereby increasing reliability at high temperature.

The organic particles may have a specific average particle diameter, and a difference in refractive index between the organic particles and the (meth)acrylic copolymer may be small. Thus, even though the adhesive layer includes organic particles, the adhesive layer may secure high transparency. The organic particles may include organic nanoparticles having an average particle diameter of about 10 nm to 400 nm, specifically 10 nm to 300 nm, more specifically 10 nm to 200 nm, and more specifically 50 nm to 150 nm. Within the above range, agglomeration of the organic nanoparticles may be prevented, the organic nanoparticles may not affect the folding of the adhesive layer, and the adhesive layer may exhibit excellent transparency. A refractive index difference between the organic particles and the (meth)acrylic based copolymer may be about 0.05 or less, specifically 0 or more and 0.03 or less, and more specifically 0 or more and 0.02 or less. Within the above range, the adhesive layer relay exhibit excellent transparency. The organic particles may have a refractive index of about 1.40 to 1.70, and specifically about 1.48 to about 1.60. Within the above range, the adhesive layer may exhibit excellent transparency.

In one embodiment, the organic nanoparticles may be core-shell type organic nanoparticles, and the core and the shell may satisfy the following Equation 1: when the organic nanoparticles have the core-shell type particle form, the adhesive layer may exhibit excellent foldability, and excellent balance properties between elasticity and flexibility.

Tg(c)<Tg(s) [Equation 1]

(where, in Equation 1, Tg (c) is the glass transition temperature (unit: ° C.) of the core and Tg (s) is the glass transition temperature (unit: ° C.) of the shell)

In the present specification, the term “shell” refers to an outermost layer among the organic nanoparticles. The core may be one spherical particle. However, the core may further include an additional layer surrounding the spherical particles as long as the core has the glass transition temperature.

Specifically, the glass transition temperature of the core may range from about −150° C. to 10° C., specifically from about −150° C. to −5° C., and more specifically from about −150° C. to −20° C. Within the above range, the adhesive layer can have a viscoelasticity effect at low temperature and/or at room temperature. The core may include at least one of polyalkyl (meth)acrylate and polysiloxane each having the above-described glass transition temperature.

The polyalkyl (meth)acrylate may include one or more of polymethyl acrylate, polyethyl acrylate, polypropyl acrylate, polybutyl acrylate, polyisopropyl acrylate, polyhexyl acrylate, polyhexyl methacrylate, polyethylhexyl acrylate, and polyethylhexyl methacrylate, but the present invention is not necessarily limited thereto.

The polysiloxane may be, for example, an organosiloxane (co)polymer. The organosiloxane (co)polymer may be used as a non-crosslinked or crosslinked organosiloxane (co)polymer. The crosslinked organosiloxane (co)polymer may be used to secure impact resistance and colorability. The crosslinked organosiloxane (co)polymer is a crosslinked organosiloxane, and specifically, the crosslinked organosiloxane (co)polymer may include crosslinked dimethylsiloxane, methylphenylsiloxane, diphenylsiloxane, and mixtures of two or more thereof. With a copolymer of two or more organosiloxanes, a refractive index may be controlled to have about 1.41 to about 1.50.

A crosslinked state of the organosiloxane (co)polymer may be determined based on the degree of dissolution in various organic solvents. As the crosslinked state is increased, the degree of dissolution by the solvent is reduced. Acetone, toluene, or the like may be used as a solvent for determining the crosslinked state, and specifically, the organosiloxane (co)polymer may have a part that is not dissolved in acetone or toluene. The organosiloxane copolymer may have about 30% or more of insolubles in toluene.

In addition, the organosiloxane (co)polymer may further include an alkyl acrylate crosslinked polymer. The alkyl acrylate crosslinked polymer may include methyl acrylate, ethyl acrylate, n-butyl acrylate, 2-ethylhexyl acrylate, and the like. For example, n-butyl acrylate or 2-ethylhexyl acrylate having a low glass transition temperature may be used.

Specifically, the glass transition temperature of the shell may range from about 15° C. to 150° C., specifically from about 35° C. to 150° C., and more specifically from 50° C. to 140° C. Within the above range, the dispersibility of the organic nanoparticles in the (meth)acrylic copolymer may be excellent. The shell may include polyalkyl methacrylate having the above-described glass transition temperature. For example, the shell may include one or more of polymethyl methacrylate (PMMA), polyethyl methacrylate, polypropyl methacrylate, polybutyl methacrylate, polyisopropyl methacrylate, polyisobutyl methacrylate, and polycyclohexyl methacrylate, but the present invention is not necessarily limited thereto.

The core may be included in an amount of about 30 wt % to 99 wt %, specifically about 40 wt % to about 95 wt %, and more specifically about 50 wt % to about 90 wt % in the organic nanoparticles. Within the above range, it is possible to improve the foldability of the optical laminate in a wide temperature range.

The shell may be included in an amount of about 1 wt % to about 70 wt %, specifically about 5 wt % to about 60 wt %, and more specifically about 10 wt % to about 50 wt % in the organic nanoparticles. Within the above range, it is possible to improve the foldability of the optical laminate in a wide temperature range.

The organic particles, for example, the organic nanoparticles, may be prepared by an emulsion polymerization method, but the present invention is not limited thereto.

The organic particles nay be included in an amount of about 0.1 parts by weight to about 20 parts by weight, for example, about 0.1 parts by weight, about 0.5 parts by weight, about 1 parts by weight, about 2 parts by weight, about 3 parts by weight, about 4 parts by weight, about 5 parts by weight, about 6 parts by weight, about 7 parts by weight, about 8 parts by weight, about 9 parts by weight, about 10 parts by weight, about 11 parts by weight, about 12 parts by weight, about 13 parts by weight, about 14 parts by weight, about 15 parts by weight, about 16 parts by weight, about 17 parts by weight, about 18 parts by weight, about 19 parts by weight, or about 20 parts by weight, specifically, about 0.5 parts by weight to about 10 parts by weight, and more specifically, about 0.5 parts by weight to about 5 parts by weight, based on 100 parts by weight of the monomer mixture. Within the above range, viscoelasticity, modulus, and restoring force of the adhesive layer may be balanced, and the adhesive layer can achieve excellent folding performance even at high temperature.

The adhesive layer composition may further include a silicone-containing (meth)acrylic based compound.

The silicone-containing (meth)acrylic based compound may contain a (meth)acrylate group as a photo-curing reaction group, through which the silicone-containing (meth)acrylic based compound is coupled to a hydroxyl group-containing (meth)acrylic based copolymer through photo-outing reaction. Photo-curing improves flowability of the adhesive layer at high temperature and allows silicone-containing parts of the silicone-containing (meth)acrylic based compound to be easily moved towards a surface of the adhesive layer, thereby reducing peel strength of the adhesive layer at high temperature. In addition, when the temperature is changed to room temperature, the silicone-containing parts are moved again into the adhesive layer to increase the peel strength of the adhesive layer, thereby enabling reversible variation in peel strength even after repeated temperature changes between room temperature and high temperature. This enables the adhesive layer to have sufficient peel strength at room temperature for excellent adhesion to the adherend, and reduced peel strength at high temperature for excellent reworkability at high temperature. In particular, the silicone-containing (meth)acrylic compound can provide excellent reworkability even in repeated high-temperature rework operations due to recent microfabrication and elaboration

In one embodiment, the adhesive layer formed of an adhesive layer composition including a silicone-containing (meth)acrylic based compound may have a peel strength ratio of about 80% or more as calculated by the following Equation 2. By satisfying Equation 2, reversible variation in peel strength is enabled even in after repeated temperature changes between room temperature and high temperature, thereby enabling repeated reworking operations and securing sufficient peel strength even after reworking to have excellent reliability. Preferably, the peel strength ratio of Equation 2 may be, for example, 80%, 81%, 87%, 83%, 84%, 85%, 86%, 87%, 88%, 89%, 90%, 91%, 92%, 93%, 94%, 95%, 96%, 97%, 98%, 99%, or 100%, and specifically may range from about 80% to 100%.

Peel strength ratio=P3/P1×100 [Equation 2]

(where, in Equation 2,
P1 is peel strength of the adhesive layer at 25° C. (unit: gf/inch), and
P3 is peel strength of the adhesive layer at 25° C. (unit: gf/inch), as measured after 10 cycles of peel strength testing, in which one cycle refers to an operation of leaving the adhesive layer at 25° C. for 30 minutes, heating the adhesive layer from 25° C. to 80° C. at a heating rate of 5° C./min, leaving the adhesive layer at 80° C. for 24 hours, and cooling the adhesive layer from 80° C. to 25° C. at a cooling rate of 5° C./min.)

The silicone-containing (meth)acrylic based compound is not included in a monomer mixture for the hydroxyl group-containing (meth)acrylic based copolymer, but is included in the adhesive composition after polymerization of the hydroxyl group-containing (meth)acrylic based copolymer. Through this process, the effects of the present invention can be easily realized.

The silicone-containing (meth)acrylic based compound may include an organopolysiloxane having at least one (meth)acrylate group at an end thereof. The (meth)acrylate group may be introduced into a side chain portion, one end, or both ends of the organopolysiloxane, but preferably, one end or both ends thereof, and more preferably, one end thereof to facilitate movement of the silicone-containing parts.

The silicone-containing (meth)acrylic based compound may include one or more of an organopolysiloxane having a (meth)acrylate group at one end thereof and an organopolysiloxane having (meth)acrylate groups at both ends thereof.

The silicone-containing (meth)acrylic based compound may have a functional group equivalent weight of about 4,000 to 20,000 g/mol, for example, 4000 g/mol, 5000 g/mol, 6000 g/mol, 7000 g/mol, 8000 g/mol, 9000 g/mol, 10000 g/mol, 11000 g/mol, 12000 g/mol, 13000 g/mol, 14000 g/mol, 15000 g/mol, 16000 g/mol, 17000 g/mol, 18000 g/mol, 19000 g/mol, or 20000 g/mol, and preferably 4,000 g/mol to 15,000 g/mol. Within the above range, through photo-curing reaction with the hydroxyl group-containing (meth)acrylic based copolymer, peel strength at room temperature may be increased and side reaction can be suppressed.

The silicone-containing (meth)acrylic based compound may be a liquid at room temperature to facilitate manufacture of the adhesive layer and increase transparency of the adhesive layer and flowability of the silicone-containing parts. In one embodiment, the silicone-containing (meth)acrylic based compound may have a viscosity of about 50 to 300 mm²/s, and preferably 50 to 250 mm²/s, at 25° C. Within the above range, compatibility with other components in the adhesive composition may be excellent.

The silicone-containing (meth)acrylic based compound may include a dialkylsiloxane unit or a linear organopolysiloxane compound containing a diarylsiloxane unit.

In one embodiment, the silicone-containing (meth)acrylic based compound may be represented by Chemical Formula 1 or 2.

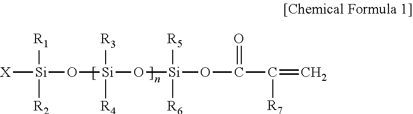

(where, in Chemical Formula 1,
R₁, R₂, R₃, R₄, R₅, and R₆ are each independently a hydrogen atom, a C1 to C10 alkyl group, or a C6 to C10 aryl group,
R₇ is a methyl group or hydrogen,
X is a methyl group, an ethyl group, a methoxy group, or an ethoxy group, and n is an integer of 100 to 500)

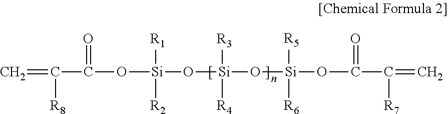

(where, in Chemical Formula 2,
R₁, R₂, R₃, R₄, R₅, and R₆ are each independently a hydrogen atom, a C1 to C10 alkyl group, or a C6 to C10 aryl group,
R₇ and R₈ are each independently a methyl group or hydrogen, and
n is an integer of 50 to 250)

Preferably, in Chemical Formula 1 and Chemical Formula 2, R₁ to R₆ are each independently a C1 to C5 alkyl group, for example, a methyl group, an ethyl group, a propyl group, a butyl group, or a pentyl group.

The silicone-containing (meth)acrylic based compound may be included in an amount of about 0.1 parts by weight to 5 parts by weight, for example, 0.1 parts by weight, 0.2 parts by weight, 0.5 parts by weight, 1.0 parts by weight, 1.5 parts by weight, 2.0 parts by weight, 2.5 parts by weight, 3.0 parts by weight, 3.5 parts by weight, 4.0 parts by weight, 4.5 parts by weight, 5.0 parts by weight, and preferably 0.3 parts by weight to 5 parts by weight, based on 100 parts by weight of the hydroxyl group-containing (meth)acrylic based copolymer Within the above range, the silicone-containing (meth)acrylic based compound can be prevented from bleeding out from the adhesive layer at high temperature while enabling reversible variation in peel strength according to a temperature change.

The adhesive layer composition may further include a crosslinking agent.

The crosslinking agent can improve mechanical strength of the adhesive layer by increasing a crosslinking degree of the adhesive layer composition. The crosslinking agent may include a polyfunctional (meth)acrylate capable of being cured with active energy lines. In an embodiment, the crosslinking agent may include bifunctional (meth)acrylates, such as 1,4-butanediol di(meth)acrylate, 1,6-hexanediol di(meth)acrylate, 1,8-octanediol di(meth)acrylate, neopentyl glycol di(meth)acrylate, polyethylene glycol di(meth)acrylate, neopentyl glycol adipate di(meth)acrylate, dicyclopentanyl di(meth)acrylate, caprolactone-modified dicyclopentenyl di(meth)acrylate, ethylene oxide-modified di(meth)acrylate, di(meth)acryloxyethyl isocyanurate, allylated cyclohexyl di(meth)acrylate, tricyclodecane dimethanol (meth)acrylate, dimethylol dicyclopentane di(meth)acrylate, ethylene oxide-modified hexahydrophthalic acid di(meth)acrylate, tricyclodecane dimethanol (meth)acrylate, neopentyl glycol-modified trimethylpropane di(meth)acrylate, adamantane di(meth)acrylate, and 9,9-bis[4-(2-acryloyloxyethoxy)phenyl]fluorene; trifunctional acrylates, such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, trifunctional urethane (meth)acrylates, and tris(meth)acryloxyethyl isocyanurate; tetrafunctional acrylates, such as diglycerin tetra(meth)acrylate and pentaerythritol tetra(meth)acrylate; pentafunctional acrylates, such as dipentaerythritol penta(meth)acrylate; and hexafunctional acrylates, such as dipentaerythritol hexa(meth)acrylate, caprolactone-modified dipentaerythritol hexa(meth)acrylate, and urethane (meth)acrylates (for example, reaction products of an isocyanate monomer and trimethylolpropane tri(meth)acrylate), but the present invention is not limited thereto. These may be used alone or in combination of two or more. Preferably, the crosslinking agent may include a polyfunctional (meth)acrylate of a polyhydric alcohol. The crosslinking agent may be included in an amount of about 0 parts by weight to 10 parts by weight, specifically 0.001 parts by weight to 7 parts by weight, and specifically 0.01 parts by weight to 5 parts by weight, based on 100 parts by weight of the monomer mixture. Within the above range, excellent adhesive strength and increased reliability can be achieved.

The adhesive layer composition may further include the above-described heteroalicyclic group-containing monomer. The heteroalicyclic group-containing monomer is substantially the same as those described above.

The heteroalicyclic group-containing monomer may be included in an amount of about 0.1 parts by weight to 20 parts by weight, and preferably 0.5 parts by weight to 15 parts by weight, and 1 parts by weight to 10 parts by weight, based on 100 parts by weight of the monomer mixture. Within the above range, the optical laminate may have excellent flexural reliability at low temperature and high temperature and/or high humidity.

The adhesive layer composition may further include a silane coupling agent. The silane coupling agent may include any conventional one known in the art. For example, the silane coupling agent may include one or more selected from the group consisting of a silicon compound having an epoxy structure such as 3-glycidoxypropyltrimethoxysilane, 3-glycidoxypropyltriethoxysilane, 3-glycidoxypropylmethyldimethoxysilane, and 2-(3,4-epoxycyclohexyl)ethyltrimethoxysilane; a polymerizable unsaturated group-containing silicon compound such as vinyltrimethoxysilane, vinyltriethoxysilane, (meth)acryloxypropyltrimethoxysilane; an amino group-containing silicon compound such as 3-aminopropyltrimethoxysilane, 3-amino propyltriethoxysilane, N-(2-aminoethyl)-3-aminopropyltrimethoxysilane, and N-(2-aminoethyl)-3-aminopropylmethyldimethoxysilane; and 3-chloropropyltrimethoxysilane, but the present invention is not limited thereto Preferably, the silane coupling agent having an epoxy structure may be used. The silane coupling agent may be included in an amount of about 0 parts by weight to 1.0 parts by weight, specifically 0.05 parts by weight to 0.5 parts by weight, based on 100 parts by weight of the monomer mixture. Within the above range, there is an effect of increasing reliability.

The adhesive layer composition may selectively further include a typical additive, such as a curing accelerator, an ionic liquid, a lithium salt, an inorganic filler, a softener, a molecular weight regulator, an antioxidant, an anti-aging agent, a stabilizer, an adhesion-imparting resin, a reforming resin (polyol, phenol, acrylic, polyester, polyolefin, epoxy, epoxidized polybutadiene resin, or the like), a leveling agent, a defoamer, a plasticizer, a dye, a pigment (a coloring pigments, extender pigment, or the like), a treating agent, a UV blocking agent, a fluorescent whitening agent, a dispersant, a heat stabilizer, a photostabilizer, a UV absorber, an anti-static agent, a coagulant, a lubricant, a solvent, or the like.

The adhesive layer composition may be prepared by partially polymerizing a monomer mixture for a (meth)acrylic based copolymer, and including an initiator and the like. The crosslinking agent, the silane coupling agent, the additive, and the like described above may be further added. The adhesive composition may be prepared by partially polymerizing a monomer mixture for a (meth)acrylic based copolymer to prepare a viscous liquid including a hydroxyl group-containing (meth)acrylic based copolymer (prepolymer) and an unpolymerized monomer mixture, and then adding an initiator and the like to the viscous liquid. The crosslinking agent, the silane coupling agent, the additive, and the like described above may be further added to the viscous liquid. The partial polymerization may include solution polymerization, suspension polymerization, photopolymerization, bulk polymerization, or emulsion polymerization. Specifically, the solution polymerization may be performed at 50° C. to 100° C. by adding an initiator to the monomer mixture. The initiator may include an acetophenone-based radical photopolymerization initiator, including 2,2-dimethoxy-2-phenylacetophenone or the like. The partial polymerization may be performed to achieve a viscosity of about 1,000 cP to 10,000 cP at 25° C., and specifically, about 4,000 cP to 9,000 cP.

In one embodiment, the first adhesive layer may be formed of an adhesive layer composition including a monomer mixture for a hydroxyl group-containing (meth)acrylic based copolymer, and an initiator. The second adhesive layer may be formed of an adhesive layer composition including a monomer mixture for a hydroxyl group-containing (meth)acrylic based copolymer, an initiator, and a silicone-containing (meth)acrylic based compound. This can help the first adhesive layer side to provide high adhesiveness and the second adhesive layer side to provide reworkability at high temperature, a simultaneously, help the optical laminate to provide excellent foldability,

In one embodiment, each of the adhesive layer composition for the first adhesive layer and the adhesive layer composition for the second adhesive layer may further include one or more of the organic particles and the inorganic particles described above.

The first adhesive layer or the second adhesive layer may be prepared by a typical method. For example, the first adhesive layer or the second adhesive layer may be prepared by coating a release film with an adhesive layer composition, followed by curing. The curing may include irradiation with a low pressure lamp at a wavelength of about 300 mil to about 400 nm and at a dose of about 400 mJ/cm² to 3000 mJ/cm² under an oxygen-free condition.

The first adhesive layer (10) and the second adhesive layer (20) may each have the same or different thicknesses. Specifically, each of the first adhesive layer (10) and the second adhesive layer (20) may have a thickness of about 10 μm to 100 μm, and preferably about 20 μm to 50 μm.

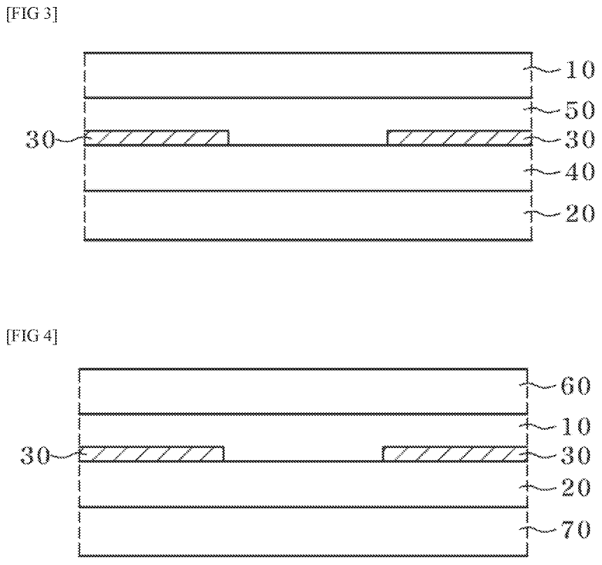

Hereinafter, an optical laminate according to another embodiment of the present invention will be described with reference to FIG. 3.

Referring to FIG. 3, the optical laminate includes a second adhesive layer (20), and a second protective layer (40), a first protective layer (50), and a first adhesive layer (10), which are sequentially laminated on an upper surface of the second adhesive layer (20), and a light blocking part (30) is formed between the second protective layer (40) and the first protective layer (50). The optical laminate according to another embodiment of the present invention is substantially the same as the optical laminate of one embodiment of the present invention, except that the first protective layer (50) and the second protective layer (40) are further included.

Each of the first protective layer (50) and the second protective layer (40) may be formed in contact with at least one surface of the light blocking part (30). The light blocking part (30) may be formed at an edge of the second protective layer (40) or the first protective layer (50), and may be impregnated in at least one of the second protective layer (40) and the first protective layer (50).

FIG. 3 illustrates the optical laminate including both the first protective layer (50) and the second protective layer (40). However, the optical laminate including only the first protective layer (50) or only the second protective layer (40) may also be included in the scope of the present invention,

The first protective layer (50) is formed on an upper surface of the light blocking part (30) to act as an overcoat layer configured to protect the light blocking part (30). Preferably, the first protective layer (50) may be formed on a lower surface of the first adhesive layer (10). The second protective layer (40) is formed on the lower surface of the light blocking part (30) to protect the light blocking part (30). Preferably, the second protective layer (40) may be formed on the upper surface of the second adhesive layer (20).

The first protective layer (50) and the second protective layer (40) may each be formed of a typical coating layer material known to those skilled in the art, as long as it is optically transparent and does not affect the effects of the present invention. In particular, each of the first protective layer (50) and the second protective layer (40) may be formed of a material that provides an appropriate range of modulus so that the light blocking part (30) can realize a light blocking function even in a wide range of temperatures and the optical laminate can provide foldability. For example, each of the first protective layer (50) and the second protective layer (40) may , be formed of a (meth)acrylic based, epoxy based, or silicone based material.

The laminate of the first protective layer (50), the light blocking part (30), and the second protective layer (40) may have a thickness of about 50 μm or less, and preferably 5 μm to 20 μm. Within the above range, it is possible to help to provide light blocking properties, adhesiveness, and excellent foldability.

A thickness of the light blocking part (30) may be less than a thickness of the first protective layer (50) or the second protective layer (40). Accordingly, the light blocking layer (30) may be included in an interface of the first protective layer (50) or the second protective layer (40), and flexural reliability of the optical laminate can be secured.

In one embodiment, the thickness of the light blocking part (30) may be about 0.01% to 50%, for example, 0.01%, 0.1%, 1%, 5%, 10%, 15%, 20%, 25%, 30%, 35%, 40%, 45%, or 50%, and preferably about 1% to 30% of the thickness of the first protective layer (50) or the second protective layer (40). Within the above range, the light blocking part (30) may be included in the interface of the first protective layer (50) or the second protective layer (40), and may not affect the flexural reliability of the optical laminate.

The thickness of the light blocking part (30) may range from 1.0 μm to 25 μm, for example, 1 μm, 5 μm, 10 μm, 15 μm, 20 μm, or 25 μm, and preferably from 1.0 μm to 10 μm. Within the above range, the light blocking part (30) may be included in the interface of the first protective layer (50) or the second protective layer (40), light blocking properties can be secured, and the optical laminate can be reduced in thickness.

The light blocking part (30) may be formed of the above-described composition. An optical laminate according to still another embodiment of the present invention will be described with reference to FIG. 4.

Referring to FIG. 4, the optical laminate may include a second adhesive layer (20), a first adhesive layer (10) laminated on an upper surface of the second adhesive layer (20), and a light blocking part (30) laminated between the second adhesive layer (20) and the first adhesive layer (10), and may further include a second adherend (70) laminated on a lover surface of the second adhesive layer (20) and a first adherend (60) laminated on an upper surface of the first adhesive layer (10). The light blocking part (30) may be formed at an edge of the first adhesive layer (10) or the second adhesive layer (20), and the light blocking part (30) may be impregnated in at least one of the first adhesive layer (10) and the second adhesive layer (20). The optical laminate according to still another embodiment of the present invention is substantially the same as the optical laminate of one embodiment of the present invention, except that the second adherend (70) and the first adherend (60) are further included.

The first adherend (60) may include various optical elements included in the optical display device. For example, the first adherend (60) may include a window film. The window film may include a base film and a hard coating layer formed on an upper surface of the base film. The first adhesive layer (10) may be adhered to the base film of the window film. The base film may include a film formed of an optically transparent resin. For example, the resin may include one or more of polyester including polyethylene terephthalate (PET), polybutylene terephthalate, polyethylene naphthalate, polybutylene naphthalate and the like, cellulose ester including acryl, cyclic olefin polymer (COP), triacetyl cellulose (TAC) and the like, polyvinyl acetate, polyvinyl chloride (PVC), polynorbonene, polycarbonate (PC), polyamide (PI), polyamide, polyacetal, polyphenylene ether, polyphenylene sulfide, polysulfone, polyethersulfone, polyarylate, and polyimide, but the present invention is not limited thereto.

The second adherend (70) may include various optical elements included in the optical display device. For example, the second adherend (70) may include a polarizer, a polarizing plate, a brightness enhancement film, an anti-reflection film, various optical films, a panel for a display device, and the like.

The optical member of the present invention includes the optical laminate of the present invention.

The optical display device of the present invention includes the optical laminate or the optical member of the present invention.

The optical display device may include a flexible or non-flexible optical display device. In one embodiment, the optical display device may include a light-emitting display device including an organic light-emitting display device or the like, a liquid crystal display device, and the like, but the present invention is not limited thereto.

A method of manufacturing an optical laminate according to one embodiment of the present invention will be described with reference to FIG. 5.

Referring to FIG. 5, the optical laminate may be manufactured by a method including operations of forming a light blocking part (30) on an upper surface of a second adhesive layer (20), and laminating a first adhesive layer (10) on the upper surface of each of the second adhesive layer (20) and the light blocking part (30).

A composition for forming each of the light blocking part (30), the second adhesive layer (20), and the first adhesive layer (10) is substantially the same as described above.

The light blocking part (30) may be formed on the upper surface of the second adhesive layer (20) by a photoresist method. Specifically, the composition for the light blocking part (30) may be applied on the upper surface of the second adhesive layer (20) to a predetermined thickness and then cured and developed by using a photomask. A more detailed photoresist method may be performed with reference to conventional methods known to those skilled in the art. The adhesive layer can be protected by further laminating release films (1) and (2) on an upper surface of the first adhesive layer (10) and a lower surface of the second adhesive layer (20), respectively.

Although not shown in FIG. 5, a process of cutting the laminate including the release film (2), the second adhesive layer (20), the light blocking part (30), the first adhesive layer (10), and the release film (1) to a predetermined size may be additionally included.

A method of manufacturing the optical laminate according to another embodiment of the present invention will be described with reference to FIG. 6.

Referring to FIG. 6, the optical laminate may be manufactured by a method including operations of preparing a laminate including a second protective layer (40), a light blocking part (30), and a first protective layer (50), laminating a first adhesive layer (10) on the first protective layer (50) side, and laminating a second adhesive layer (20) on the second protective layer (40) side.

A composition for forming each of the first protective layer (50), the second protective layer (40), the light blocking part (30), the second adhesive layer (20), and the first adhesive layer (10) is substantially the same as described above.

The light blocking part (300 may be formed on an upper surface of the second protective layer (40) by a photoresist method. Specifically, the composition for the light blocking part (30) may be applied on the upper surface of the second protective layer (40) to a predetermined thickness and then cured and developed by using a photomask. A more detailed photoresist method may be performed with reference to conventional methods known to those skilled in the art. The protective layer can be protected by further laminating release films (1) and (2) on an upper surface of the first protective layer (50) and a lower surface of the second protective layer (40), respectively.

Although not shown in FIG. 6, a process of cutting the laminate including the release film (2), the second adhesive layer (20), the second protective layer (40), the light blocking part (30), the first protective layer (50), the first adhesive layer 10, and the release film (1) to a predetermined size may be additionally included.

### Modes of the Invention

Hereinafter, the configurations and operations of the present invention will be described in more detail through preferred examples of the present invention. However, these examples are provided as preferred examples of the present invention and are not to be construed as limiting the scope of the present invention in any way.

### EXAMPLES

### (1) Preparation of First Adhesive Layer

Organic nanoparticles were prepared by an emulsion polymerization method. A core was formed of polybutyl acrylate, and a shell was formed of polymethyl methacrylate. In the organic nanoparticles, the shell was included in an amount of 35 wt %, and the core was included in an amount of 65 wt %. The organic nanoparticles had an average particle diameter of 100 nm and a refractive index of 1.48.

100 parts by weight of a monomer mixture including 17 parts by weight of 4-hydroxybutyl acrylate and 83 parts by weight of 2-ethylhexyl acrylate, 1 parts by weight of the organic nanoparticles, and 0.03 parts by weight of Irgacure 651 (2,2-dimethoxy-2-phenylacetophenone, BASF Co., Ltd.) as an initiator were mixed well in a reactor. Dissolved oxygen in the reactor was exchanged with nitrogen gas, and the mixture was partially polymerized by irradiating ultraviolet rays using a low-pressure mercury lamp for several minutes to prepare a viscous liquid having a viscosity of 5,000 cPs at 25° C. 0.5 parts by weight of Irgacure 184 (1-hydroxycyclohexyl phenyl ketone, BASF Co., Ltd.) as an initiator was added to the viscous liquid and mixed to prepare an adhesive composition. The adhesive composition was applied between two sheets of release-treated polyethylene terephthalate (PET) film, and irradiated with ultraviolet rays at a dose of 2000 mJ/cm2 to produce a first adhesive layer having a thickness of 50 μm and an adhesive sheet of PET film. The prepared first adhesive layer had a peel strength of 1,000 gf/inch at 25° C.

### (2) Preparation of Second Adhesive Layer

Organic nanoparticles were prepared by emulsion polymerization. A core was formed of polybutyl acrylate, and a shell was formed of polymethyl methacrylate. In the organic nanoparticles, the shell was included in an amount of 35 wt %, and the core was included in an amount of 65 wt %. The organic nanoparticles satisfied Equation 1, and had an average particle diameter of 100 nm and a refractive index of 1.48.

100 parts by weight of a mixture including 82 parts by weight of 2-ethylhexyl acrylate, 10 parts by weight of 2-hydroxyethyl acrylate, 7 parts by weight of acryloylmorpholine, 1 parts by weight of organic nanoparticles, and 0.005 parts by weight of a photoinitiator (Omnirad 651, 2,2-dimethoxy-2-phenylacetophenone, IGM) were mixed well in a reactor. Dissolved oxygen in the reactor was exchanged with nitrogen gas, and the monomer mixture was partially polymerized by irradiating ultraviolet rays using a low-pressure mercury lamp for several minutes to prepare a viscous liquid having a viscosity of 500 cPs to 5,000 cPs at 25° C. A composition for a second adhesive layer was prepared by including 0.1 parts by weight of 1,6-hexanediol diacrylate and 0.5 weight parts by weight of polydimethylsiloxane (Shin-etsu Chemical Co., Ltd, X-22-2426) having (meth)acrylate groups at both ends thereof. The prepared composition was applied to a PET film (thickness: 75 μm) as a release film, and the PET film (thickness: 75 μm) was laminated again on the obtained release layer, and an adhesive sheet of PET film (thickness: 75 μm)/second adhesive layer (thickness: 25 μm)/PET film (thickness: 75 μm) was prepared by irradiating with ultraviolet rays of 2000 mJ/cm². The second adhesive layer had a peel strength of 1,300 gf/inch at 25° C.

### (3) Preparation of Optical Laminate

A light blocking part was formed by applying a composition for the light blocking part including carbon black to an edge surface of the prepared second adhesive layer to a predetermined thickness and curing the same. Thereafter, the prepared first adhesive layer was laminated to prepare an optical laminate having a cross-sectional view of FIG. 1 and an exploded perspective view of FIG. 2. The optical laminate had excellent reworkability and foldability at high temperature when evaluated by the above-described method.

### (4) Preparation of Optical Laminate

A light blocking part was formed at an edge of an upper surface of a second protective layer (acrylic coating layer) by treating the upper surface of the second protective layer with the above-described composition for the light blocking layer by a photoresist method. A first protective layer (overcoat layer) vas formed on the upper surface of the second protective layer on which the light blocking part is formed, and the first protective layer was formed to cover the light blocking part and the second protective layer. A thickness of the laminate of the second protective layer, the light blocking part, and the first protective layer was 10 μm.

An optical laminate having a cross-sectional view of FIG. 3 was manufactured by laminating the second adhesive layer on a lower surface of the second protective layer and laminating the first adhesive layer on an upper surface of the first protective layer. The optical laminate had excellent reworkability and foldability at high temperature when evaluated by the above-described method.

Simple modification or changes of the present invention can be easily performed by those of ordinary skill in the art, and it can be regarded that such modifications or changes are included in the scope of the present invention.

1. An optical laminate comprising:
a second adhesive layer; a first adhesive layer laminated on the second adhesive layer; and
a light blocking part laminated between the first adhesive layer and the second adhesive layer.

2. The optical laminate of claim 1, wherein the light blocking layer is formed at an edge of the first adhesive layer or the second adhesive layer.

3. The optical laminate of claim 1, wherein a thickness of the light blocking layer is about 0.01% to 50% of a thickness of the first adhesive layer or the second adhesive layer.

4. The optical laminate of claim 1, wherein the first adhesive layer and the second adhesive layer each have a storage modulus of about 400 kPa or less at −20° C.

5. The optical laminate of claim 1, wherein the first adhesive layer and the second adhesive layer each have a storage modulus of about 5 kPa to 50 kPa at 60° C.

6. The optical laminate of claim 1, wherein each of the first adhesive layer and the second adhesive layer is a (meth)acrylic based adhesive layer.

7. The optical laminate of claim 1, wherein the first adhesive layer is formed of an adhesive layer composition including a monomer mixture for a hydroxyl group-containing (meth)acrylic based copolymer and an initiator.

8. The optical laminate of claim 7, wherein the adhesive layer composition further includes one or more of organic particles and inorganic particles.

9. The optical laminate of claim 1, wherein the second adhesive layer is formed of an adhesive layer composition including a monomer mixture for a hydroxyl group-containing (meth)acrylic based copolymer, an initiator, and a silicone-containing (meth)acrylic based compound.

10. The optical laminate of claim 9, wherein the adhesive layer composition further includes one or more of organic particles and inorganic particles.

11. The optical laminate of claim 1, further comprising one or more of a first protective layer and a second protective layer that are formed between the first adhesive layer and the second adhesive layer.

12. The optical laminate of claim 11, wherein each of the first protective layer and the second protective layer is in contact with at least one surface of the light blocking part.

13. The optical laminate of claim 11, wherein
the optical laminate includes the second adhesive layer, and the second protective layer, the first protective layer, and the first adhesive layer, which are sequentially laminated on an upper surface of the second adhesive layer, and
the light blocking part is formed between the second protective layer and the first protective layer.

14. The optical laminate of claim 13, wherein the light blocking part is formed at an edge of the second protective layer or the first protective layer.

15. The optical laminate of claim 11, wherein each of the first protective layer and the second protective layer includes a (meth)acrylic based, epoxy based, or silicone based coating layer.

16. The optical laminate of claim 14, wherein a lamination thickness of the second protective layer, the light blocking part, and the first protective layer is about 50 μm or less.

17. The optical laminate of claim 1, wherein the optical laminate includes the second adhesive layer, the first adhesive layer laminated on an upper surface of the second adhesive layer, and the light blocking part laminated between the second adhesive layer and the first adhesive layer, and further includes a second adherend laminated on a lower surface of the second adhesive layer and a first adherend laminated on an upper surface of the first adhesive layer.

18. The optical laminate of claim 17, wherein the light blocking part is formed at an edge of the first adhesive layer or the second adhesive layer.

19. An optical member comprising the optical laminate of claim 1.

20. An optical display device comprising the optical laminate of claim 1.
